(19) United States
(12) Patent Application Publication
(10) Pub. No.: US 2025/0180604 A1
(43) Pub. Date: Jun. 5, 2025

(54) CHIP TESTING STRUCTURE

(71) Applicant: Taiwan Semiconductor Manufacturing Company, Ltd., Hsinchu (TW)

(72) Inventors: Kuan-Chun CHEN, Hsinchu City (TW); Kai-Yi TANG, New Taipei City (TW); Chung-Lun WANG, Hsinchu County (TW)

(21) Appl. No.: 18/526,083

(22) Filed: Dec. 1, 2023

(51) Int. Cl. G01R 1/067; G01R 1/073

(52) U.S. Cl. CPC G01R 1/0675; G01R 1/06761; G01R 1/07314

(57) ABSTRACT

A chip testing structure is provided. The chip testing structure includes a probe head including a substrate and a first needle passing through the substrate. The chip testing structure includes a wiring substrate over the probe head. The wiring substrate includes an insulating layer and a conductive structure in the insulating layer. The chip testing structure includes a housing structure over the wiring substrate. The housing structure has a chamber. The chip testing structure includes a second needle passing through the housing structure and connected to the conductive structure of the wiring substrate. The chip testing structure includes a chip-containing structure in the chamber and electrically connected to the first needle through the second needle and the conductive structure of the wiring substrate.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs.

In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs.

However, since feature sizes continue to decrease, fabrication processes continue to become more difficult to perform. Therefore, it is a challenge to form reliable semiconductor devices (e.g., chips) at smaller and smaller sizes and to accurately detect the electrical quality of chips in a wafer.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, the dimensions of the various features may be arbitrarily increased or reduced for clarity of discussion.

FIG. 1 is a cross-sectional view of a chip testing structure and a wafer, in accordance with some embodiments.

FIG. 2 is a cross-sectional view of a chip testing structure, in accordance with some embodiments.

FIG. 3 is a cross-sectional view of a chip testing structure, in accordance with some embodiments.

FIG. 4 is a cross-sectional view of a chip testing structure and a wafer, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Furthermore, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “substantially” in the description, such as in “substantially flat” or in “substantially coplanar”, etc., will be understood by the person skilled in the art. In some embodiments the adjective substantially may be removed. Where applicable, the term “substantially” may also include embodiments with “entirely”, “completely”, “all”, etc. The term “substantially” may be varied in different technologies and be in the deviation range understood by the skilled in the art. For example, the term “substantially” may also relate to 90% of what is specified or higher, such as 95% of what is specified or higher, especially 99% of what is specified or higher, including 100% of what is specified, though the present invention is not limited thereto. Furthermore, terms such as “substantially parallel” or “substantially perpendicular” may be interpreted as not to exclude insignificant deviation from the specified arrangement and may include for example deviations of up to 10°. The word “substantially” does not exclude “completely” e.g. a composition which is “substantially free” from Y may be completely free from Y.

The term “about” may be varied in different technologies and be in the deviation range understood by the skilled in the art. The term “about” in conjunction with a specific distance or size is to be interpreted so as not to exclude insignificant deviation from the specified distance or size. For example, the term “about” may include deviations of up to 10% of what is specified, though the present invention is not limited thereto. The term “about” in relation to a numerical value x may mean x±5 or 10% of what is specified, though the present invention is not limited thereto.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

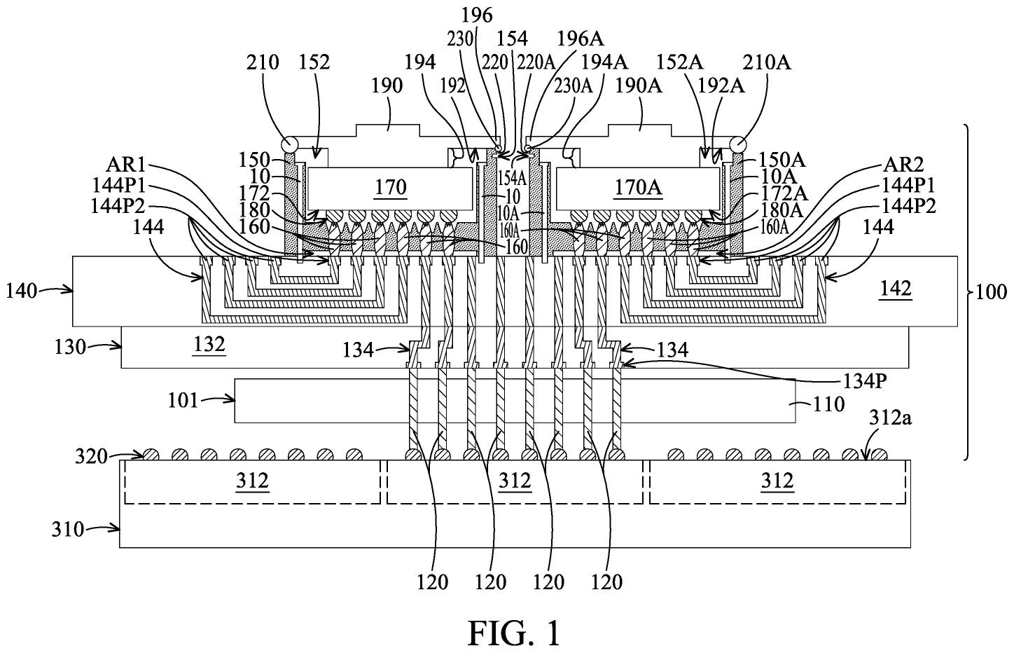

FIG. 1 is a cross-sectional view of a chip testing structure 100 and a wafer 310, in accordance with some embodiments. As show in FIG. 1, the chip testing structure 100 includes a probe head 101, a transformer substrate 130, a wiring substrate 140, housing structures 150 and 150A, needles 160 and 160A, chip-containing structures 170 and 170A, conductive bumps 180 and 180A, cover plates 190 and 190A, pivots 210 and 210A, hook-like structures 220 and 220A, and pivots 230 and 230A, in accordance with some embodiments.

The probe head 101 includes a substrate 110 and needles 120, in accordance with some embodiments. The needles 120 pass through the substrate 110, in accordance with some embodiments. The substrate 110 is made of a dielectric material such as a polymer material, glass, or ceramics, in accordance with some embodiments. The needles 120 are made of a conductive material such as metal (e.g., copper, aluminum, gold, silver, tungsten, titanium, cobalt, or ruthenium) or alloys thereof, in accordance with some embodiments.

As show in FIG. 1, the transformer substrate 130 is disposed over the probe head 101. The transformer substrate 130 includes an insulating layer 132 and a conductive structure 134, in accordance with some embodiments. The conductive structure 134 is in the insulating layer 132, in accordance with some embodiments.

The conductive structure 134 includes wiring layers, conductive vias, and conductive pads 134p, in accordance with some embodiments. The conductive vias are connected between the wiring layers and the conductive pads 134p, in accordance with some embodiments.

The insulating layer 132 is made of a dielectric material such as a polymer material, in accordance with some embodiments. The conductive structure 134 is made of a conductive material such as metal (e.g., copper, aluminum, gold, silver, tungsten, titanium, cobalt, or ruthenium) or alloys thereof, in accordance with some embodiments.

As show in FIG. 1, the wiring substrate 140 is disposed over the transformer substrate 130, in accordance with some embodiments. The wiring substrate 140 includes an insulating layer 142 and a conductive structure 144, in accordance with some embodiments. The conductive structure 144 is in the insulating layer 142, in accordance with some embodiments.

The conductive structure 134 of the transformer substrate 130 is connected between the conductive structure 144 and the needles 120, in accordance with some embodiments. The conductive structure 134 of the transformer substrate 130 is in direct contact with the conductive structure 144 of the wiring substrate 140 and the needles 120, in accordance with some embodiments.

The conductive structure 144 includes wiring layers, conductive vias, and conductive pads 144p1 and 144p2, in accordance with some embodiments. The conductive vias are connected between the wiring layers and the conductive pads 144p1 and 144p2, in accordance with some embodiments. The conductive pads 144p1 are used to connect with the needles 160, in accordance with some embodiments. The conductive pads 144p2 are used to connect with a tester (not shown), in accordance with some embodiments.

The insulating layer 142 is made of a dielectric material such as a polymer material, in accordance with some embodiments. The conductive structure 144 is made of a conductive material such as metal (e.g., copper, aluminum, gold, silver, tungsten, titanium, cobalt, or ruthenium) or alloys thereof, in accordance with some embodiments.

As show in FIG. 1, the housing structures 150 and 150A are disposed over the wiring substrate 140, in accordance with some embodiments. The housing structures 150 and 150A are in direct contact with the wiring substrate 140, in accordance with some embodiments. An air gap AR1 is between a bottom portion of the housing structure 150 and the wiring substrate 140, in accordance with some embodiments. An air gap AR2 is between a bottom portion of the housing structure 150A and the wiring substrate 140, in accordance with some embodiments.

The housing structure 150 has a chamber 152, in accordance with some embodiments. The housing structure 150A has a chamber 152A, in accordance with some embodiments. The housing structure 150 is made of a dielectric material such as a polymer material, in accordance with some embodiments.

As show in FIG. 1, pillar structures 10 pass through the housing structure 150 and extend into the wiring substrate 140, in accordance with some embodiments. The pillar structures 10 are also referred to as screw structures, in accordance with some embodiments. The pillar structures 10 are used to fix the housing structure 150 on the wiring substrate 140, in accordance with some embodiments.

As show in FIG. 1, pillar structures 10A pass through the housing structure 150A and extend into the wiring substrate 140, in accordance with some embodiments. The pillar structures 10A are also referred to as screw structures, in accordance with some embodiments. The pillar structures 10A are used to fix the housing structure 150A on the wiring substrate 140, in accordance with some embodiments.

The pillar structures 10 and 10A are harder than the housing structures 150 and 150A and the wiring substrate 140, in accordance with some embodiments. The pillar structures 10 and 10A are made of a hard material such as a metal material or a polymer material, in accordance with some embodiments.

As show in FIG. 1, needles 160 pass through the housing structure 150 and connected to the conductive structure 144 of the wiring substrate 140, in accordance with some embodiments. The needles 160 are in direct contact with the conductive structure 144 of the wiring substrate 140, in accordance with some embodiments.

As show in FIG. 1, needles 160A pass through the housing structure 150A and connected to the conductive structure 144 of the wiring substrate 140, in accordance with some embodiments. The needles 160A are in direct contact with the conductive structure 144 of the wiring substrate 140, in accordance with some embodiments.

The needles 160 and 160A are made of a conductive material such as metal (e.g., copper, aluminum, gold, silver, tungsten, titanium, cobalt, or ruthenium) or alloys thereof, in accordance with some embodiments.

The chip-containing structure 170 includes a chip or a package having one or more chips, in accordance with some embodiments. The chip-containing structure 170A includes a chip or a package having one or more chips, in accordance with some embodiments. The function of the chip-containing structure 170 is different from the function of the chip-containing structure 170A, in accordance with some embodiments.

For example, the chip-containing structures 170 and 170A are respectively one and another of a central processing unit chip, a graphic processing unit chip, a high bandwidth memory package, a memory chip, or the like, in accordance with some embodiments.

In some embodiments, the chip-containing structure 170 is a chip. In some embodiments, the chip includes a substrate, devices, and an interconnect structure over the substrate, in accordance with some embodiments. The substrate, the devices, and the interconnect layers are not shown in figures for the purpose of simplicity and clarity.

The substrate is made of an elementary semiconductor material including silicon or germanium in a single crystal structure, a polycrystal structure, or an amorphous structure. In some other embodiments, the substrate is made of a compound semiconductor, such as silicon carbide, gallium arsenide, gallium phosphide, indium phosphide, indium arsenide, an alloy semiconductor, such as SiGe, or GaAsP, or a combination thereof. The substrate may also include multi-layer semiconductors, semiconductor on insulator (SOI) (such as silicon on insulator or germanium on insulator), or a combination thereof.

In some embodiments, the devices of the chip 170 are formed in and/or over the substrate. Examples of the various devices include active devices, passive devices, other suitable elements, or a combination thereof. The active devices may include transistors or diodes formed at a surface of the substrate. The passive devices include resistors, capacitors, or other suitable passive devices.

For example, the transistors may be metal oxide semiconductor field effect transistors (MOSFET), complementary metal oxide semiconductor (CMOS) transistors, bipolar junction transistors (BJT), high-voltage transistors, high-frequency transistors, p-channel and/or n-channel field effect transistors (PFETs/NFETs), etc. Various processes, such as front-end-of-line (FEOL) semiconductor fabrication processes, are performed to form the various device elements. The FEOL semiconductor fabrication processes may include deposition, etching, implantation, photolithography, annealing, planarization, one or more other applicable processes, or a combination thereof.

In some embodiments, isolation features (not shown) are formed in the substrate. The isolation features are used to define active regions and electrically isolate various devices formed in and/or over the substrate in the active regions. In some embodiments, the isolation features include shallow trench isolation (STI) features, local oxidation of silicon (LOCOS) features, other suitable isolation features, or a combination thereof.

The interconnect structure is formed over the devices and the substrate, in accordance with some embodiments. The interconnect structure includes a dielectric layer, wiring layers, and conductive vias, in accordance with some embodiments. The wiring layers and the conductive vias are in the dielectric layer, in accordance with some embodiments. The conductive vias are electrically connected between the wiring layers and the devices, in accordance with some embodiments.

The dielectric layer is made of an oxide-containing material (e.g., silicon oxide or tetraethyl orthosilicate (TEOS) oxide), an oxynitride-containing material (e.g., silicon oxynitride), a glass material (e.g., borosilicate glass (BSG), phosphoric silicate glass (PSG), borophosphosilicate glass (BPSG), or fluorinated silicate glass (FSG)), or a combination thereof, in accordance with some embodiments.

Alternatively, the dielectric layer includes a low-k material or a porous dielectric material having a k-value which is lower than that of silicon oxide, or lower than about 3.0 or about 2.5, in accordance with some embodiments. The wiring layers and the conductive vias are made of a conductive material, such as metal (e.g., copper, aluminum, gold, silver, or tungsten) or alloys thereof, in accordance with some embodiments.

In some embodiments, the chip-containing structure 170A is a chip. In some embodiments, the chip includes a substrate, devices, and an interconnect structure over the substrate, in accordance with some embodiments. The substrate, the devices, and the interconnect layers are not shown in figures for the purpose of simplicity and clarity.

The substrate is made of an elementary semiconductor material including silicon or germanium in a single crystal structure, a polycrystal structure, or an amorphous structure. In some other embodiments, the substrate is made of a compound semiconductor, such as silicon carbide, gallium arsenide, gallium phosphide, indium phosphide, indium arsenide, an alloy semiconductor, such as SiGe, or GaAsP, or a combination thereof. The substrate may also include multi-layer semiconductors, semiconductor on insulator (SOI) (such as silicon on insulator or germanium on insulator), or a combination thereof.

In some embodiments, the devices of the chip 170A are formed in and/or over the substrate. Examples of the various devices include active devices, passive devices, other suitable elements, or a combination thereof. The active devices may include transistors or diodes formed at a surface of the substrate. The passive devices include resistors, capacitors, or other suitable passive devices.

For example, the transistors may be metal oxide semiconductor field effect transistors (MOSFET), complementary metal oxide semiconductor (CMOS) transistors, bipolar junction transistors (BJT), high-voltage transistors, high-frequency transistors, p-channel and/or n-channel field effect transistors (PFETs/NFETs), etc. Various processes, such as front-end-of-line (FEOL) semiconductor fabrication processes, are performed to form the various device elements. The FEOL semiconductor fabrication processes may include deposition, etching, implantation, photolithography, annealing, planarization, one or more other applicable processes, or a combination thereof.

In some embodiments, isolation features (not shown) are formed in the substrate. The isolation features are used to define active regions and electrically isolate various devices formed in and/or over the substrate in the active regions. In some embodiments, the isolation features include shallow trench isolation (STI) features, local oxidation of silicon (LOCOS) features, other suitable isolation features, or a combination thereof.

The interconnect structure is formed over the devices and the substrate, in accordance with some embodiments. The interconnect structure includes a dielectric layer, wiring layers, and conductive vias, in accordance with some embodiments. The wiring layers and the conductive vias are in the dielectric layer, in accordance with some embodiments. The conductive vias are electrically connected between the wiring layers and the devices, in accordance with some embodiments.

The dielectric layer is made of an oxide-containing material (e.g., silicon oxide or tetraethyl orthosilicate (TEOS) oxide), an oxynitride-containing material (e.g., silicon oxynitride), a glass material (e.g., borosilicate glass (BSG), phosphoric silicate glass (PSG), borophosphosilicate glass (BPSG), or fluorinated silicate glass (FSG)), or a combination thereof, in accordance with some embodiments.

Alternatively, the dielectric layer includes a low-k material or a porous dielectric material having a k-value which is lower than that of silicon oxide, or lower than about 3.0 or about 2.5, in accordance with some embodiments. The wiring layers and the conductive vias are made of a conductive material, such as metal (e.g., copper, aluminum, gold, silver, or tungsten) or alloys thereof, in accordance with some embodiments.

As show in FIG. 1, the conductive bumps 180 are formed over a bottom surface 172 of the chip-containing structure 170, in accordance with some embodiments. The conductive bumps 180 are made of a conductive material, such as tin, or alloys thereof, in accordance with some embodiments.

As show in FIG. 1, conductive bumps 180A are formed over a bottom surface 172A of the chip-containing structure 170A, in accordance with some embodiments. The conductive bumps 180A are made of a conductive material, such as tin, or alloys thereof, in accordance with some embodiments.

As show in FIG. 1, the chip-containing structure 170 and the conductive bumps 180 are disposed in the chamber 152, in accordance with some embodiments. The conductive bumps 180 are between the chip-containing structure 170 and the needles 160, in accordance with some embodiments. The conductive bumps 180 are in direct contact with the needles 160, in accordance with some embodiments.

The chip-containing structure 170 is electrically connected to the needles 120 through the conductive bumps 180, the needles 160, the conductive structure 144 of the wiring substrate 140, and the conductive structure 134 of the transformer substrate 130, in accordance with some embodiments.

As show in FIG. 1, the chip-containing structure 170A and the conductive bumps 180A are disposed in the chamber 152A, in accordance with some embodiments. The conductive bumps 180A are between the chip-containing structure 170A and the needles 160A, in accordance with some embodiments. The conductive bumps 180A are in direct contact with the needles 160A, in accordance with some embodiments.

The chip-containing structure 170A is electrically connected to the needles 120 through the conductive bumps 180A, the needles 160A, the conductive structure 144 of the wiring substrate 140, and the conductive structure 134 of the transformer substrate 130, in accordance with some embodiments.

As show in FIG. 1, the cover plate 190 is over the housing structure 150 and the chip-containing structure 170, in accordance with some embodiments. The cover plate 190 covers the chamber 152 of the housing structure 150, in accordance with some embodiments. The cover plate 190 is pivotally connected to the housing structure 150, in accordance with some embodiments. The cover plate 190 is connected to the housing structure 150 by a pivot 210, in accordance with some embodiments.

The cover plate 190 has a lower surface 192 and a protruding portion 194, in accordance with some embodiments. The protruding portion 194 protrudes from the lower surface 192, in accordance with some embodiments. The protruding portion 194 of the cover plate 190 is in direct contact with the chip-containing structure 170, in accordance with some embodiments.

The protruding portion 194 presses the chip-containing structure 170 toward the needles 160, in accordance with some embodiments. The cover plate 190 is made of a dielectric material such as a polymer material, in accordance with some embodiments.

As show in FIG. 1, the hook-like structure 220 is connected to an edge portion 196 of the cover plate 190, in accordance with some embodiments. The cover plate 190 is between the hook-like structure 220 and the pivot 210, in accordance with some embodiments. The hook-like structure 220 is pivotally connected to the edge portion 196, in accordance with some embodiments.

The hook-like structure 220 is connected to the edge portion 196 by a pivot 230, in accordance with some embodiments. The hook-like structure 220 hooks into a recess 154 of the housing structure 150, in accordance with some embodiments. The hook-like structure 220 is made of a dielectric material such as a polymer material, in accordance with some embodiments.

As show in FIG. 1, the cover plate 190A is over the housing structure 150A and the chip-containing structure 170A, in accordance with some embodiments. The cover plate 190A covers the chamber 152A of the housing structure 150A, in accordance with some embodiments. The cover plate 190A is pivotally connected to the housing structure 150A, in accordance with some embodiments. The cover plate 190A is connected to the housing structure 150A by a pivot 210A, in accordance with some embodiments.

The cover plate 190A has a lower surface 192A and a protruding portion 194A, in accordance with some embodiments. The protruding portion 194A protrudes from the lower surface 192A, in accordance with some embodiments. The protruding portion 194A of the cover plate 190A is in direct contact with the chip-containing structure 170A, in accordance with some embodiments.

The protruding portion 194A presses the chip-containing structure 170A toward the needles 160A, in accordance with some embodiments. The cover plate 190A is made of a dielectric material such as a polymer material, in accordance with some embodiments.

As show in FIG. 1, the hook-like structure 220A is connected to an edge portion 196A of the cover plate 190A, in accordance with some embodiments. The cover plate 190A is between the hook-like structure 220A and the pivot 210A, in accordance with some embodiments. The hook-like structure 220A is pivotally connected to the edge portion 196A, in accordance with some embodiments.

The hook-like structure 220A is connected to the edge portion 196A by a pivot 230A, in accordance with some embodiments. The hook-like structure 220A hooks into a recess 154A of the housing structure 150A, in accordance with some embodiments.

The hook-like structure 220A is made of a dielectric material such as a polymer material, in accordance with some embodiments. In some embodiments, the number of the housing structures (e.g., 150 or 150A) or the number of the chip-containing structures (e.g., 170 or 170A) of the chip testing structure 100 ranges from 1 to 10.

As show in FIG. 1, a wafer 310 is provided, in accordance with some embodiments. The wafer 310 includes chip regions 312, in accordance with some embodiments. In some embodiments, the wafer 310 includes a substrate, devices, and an interconnect structure over the substrate, in accordance with some embodiments. The substrate, the devices, and the interconnect layers are not shown in figures for the purpose of simplicity and clarity.

The substrate is made of an elementary semiconductor material including silicon or germanium in a single crystal structure, a polycrystal structure, or an amorphous structure. In some other embodiments, the substrate is made of a compound semiconductor, such as silicon carbide, gallium arsenide, gallium phosphide, indium phosphide, indium arsenide, an alloy semiconductor, such as SiGe, or GaAsP, or a combination thereof. The substrate may also include multi-layer semiconductors, semiconductor on insulator (SOI) (such as silicon on insulator or germanium on insulator), or a combination thereof.

In some embodiments, the devices of the wafer 310 are formed in and/or over the substrate. Examples of the various devices include active devices, passive devices, other suitable elements, or a combination thereof. The active devices may include transistors or diodes formed at a surface of the substrate. The passive devices include resistors, capacitors, or other suitable passive devices.

For example, the transistors may be metal oxide semiconductor field effect transistors (MOSFET), complementary metal oxide semiconductor (CMOS) transistors, bipolar junction transistors (BJT), high-voltage transistors, high-frequency transistors, p-channel and/or n-channel field effect transistors (PFETs/NFETs), etc. Various processes, such as front-end-of-line (FEOL) semiconductor fabrication processes, are performed to form the various device elements. The FEOL semiconductor fabrication processes may include deposition, etching, implantation, photolithography, annealing, planarization, one or more other applicable processes, or a combination thereof.

In some embodiments, isolation features (not shown) are formed in the substrate. The isolation features are used to define active regions and electrically isolate various devices formed in and/or over the substrate in the active regions. In some embodiments, the isolation features include shallow trench isolation (STI) features, local oxidation of silicon (LOCOS) features, other suitable isolation features, or a combination thereof.

The interconnect structure is formed over the devices and the substrate, in accordance with some embodiments. The interconnect structure includes a dielectric layer, wiring layers, and conductive vias, in accordance with some embodiments. The wiring layers and the conductive vias are in the dielectric layer, in accordance with some embodiments. The conductive vias are electrically connected between the wiring layers and the devices, in accordance with some embodiments.

The dielectric layer is made of an oxide-containing material (e.g., silicon oxide or tetraethyl orthosilicate (TEOS) oxide), an oxynitride-containing material (e.g., silicon oxynitride), a glass material (e.g., borosilicate glass (BSG), phosphoric silicate glass (PSG), borophosphosilicate glass (BPSG), or fluorinated silicate glass (FSG)), or a combination thereof, in accordance with some embodiments.

Alternatively, the dielectric layer includes a low-k material or a porous dielectric material having a k-value which is lower than that of silicon oxide, or lower than about 3.0 or about 2.5, in accordance with some embodiments. The wiring layers and the conductive vias are made of a conductive material, such as metal (e.g., copper, aluminum, gold, silver, or tungsten) or alloys thereof, in accordance with some embodiments.

As show in FIG. 1, conductive bumps 320 are formed over a top surface 312a of each chip region 312, in accordance with some embodiments. The conductive bumps 320 are electrically connected to the wiring layers and the devices in the chip regions 312 of the wafer 310, in accordance with some embodiments. The conductive bumps 320 are made of a conductive material, such as tin, or alloys thereof, in accordance with some embodiments.

As show in FIG. 1, the needles 120 of the probe head 101 of the chip testing structure 100 are disposed on the conductive bumps 320 to test the electrical quality of each chip region 312, in accordance with some embodiments.

In a subsequent process (not shown), the wafer 310 is cut (or diced) into chips each having one of the chip regions 312, and the chip having the chip region 312 are packaged together with the chip-containing structures 170 and 170A to form a chip package structure, in accordance with some embodiments.

Since the chip testing structure 100 has the chip-containing structures 170 and 170A, the chip testing structure 100 can not only detect the electrical quality of each chip region 312 of the wafer 310, but also detect the electrical quality of the electrical connection between the chip-containing structure 170 and each chip region 312 and between the chip-containing structure 170A and each chip region 312, in accordance with some embodiments. Therefore, the chip testing structure 100 can help screen out the chip regions 312 with poor electrical connection quality before the packaging process, in accordance with some embodiments.

As a result, the chip testing structure 100 can prevent the chips having the chip regions 312 with poor electrical connection quality from being packaged, which reduces the cost of packages and improves the yield and the performance of packages, in accordance with some embodiments.

In some embodiments, if the chip-containing structures 170 and 170A have poor electrical (connection) quality, the chip-containing structures 170 and 170A may be replaced with chip-containing structures with good electrical (connection) quality, and other portions of the chip testing structure 100 may be reused. Therefore, the cost of the chip testing structure 100 is reduced, in accordance with some embodiments.

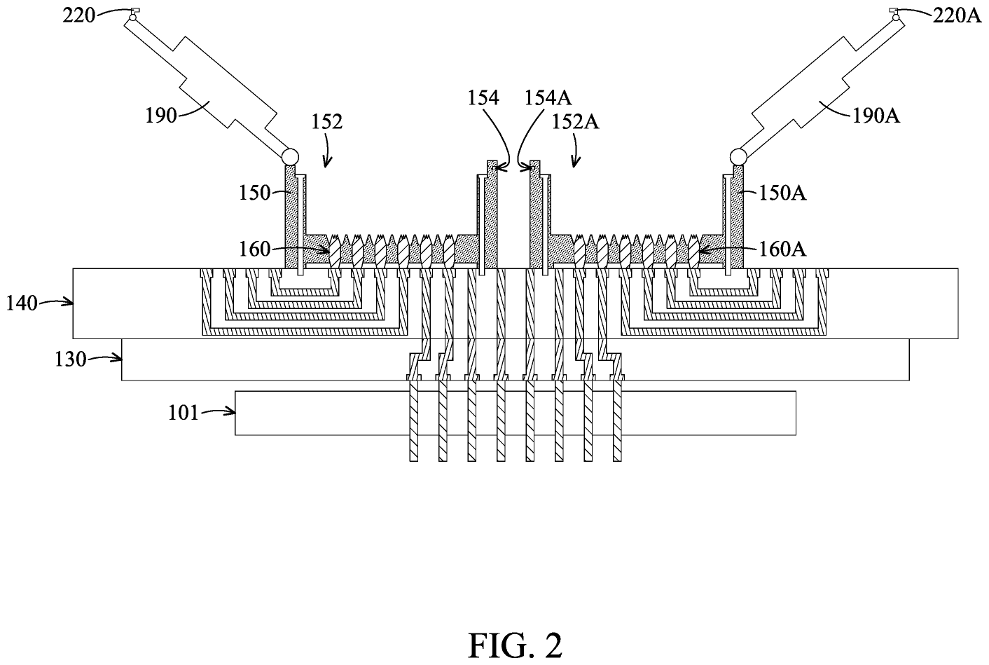

FIG. 2 is a cross-sectional view of a chip testing structure, in accordance with some embodiments. As shown in FIGS. 1 and 2, the cover plates 190 and 190A are pivotally opened, in accordance with some embodiments. As shown in FIGS. 1 and 2, the chip-containing structures 170 and 170A are removed from the chambers 152 and 152A of the housing structures 150 and 150A, in accordance with some embodiments.

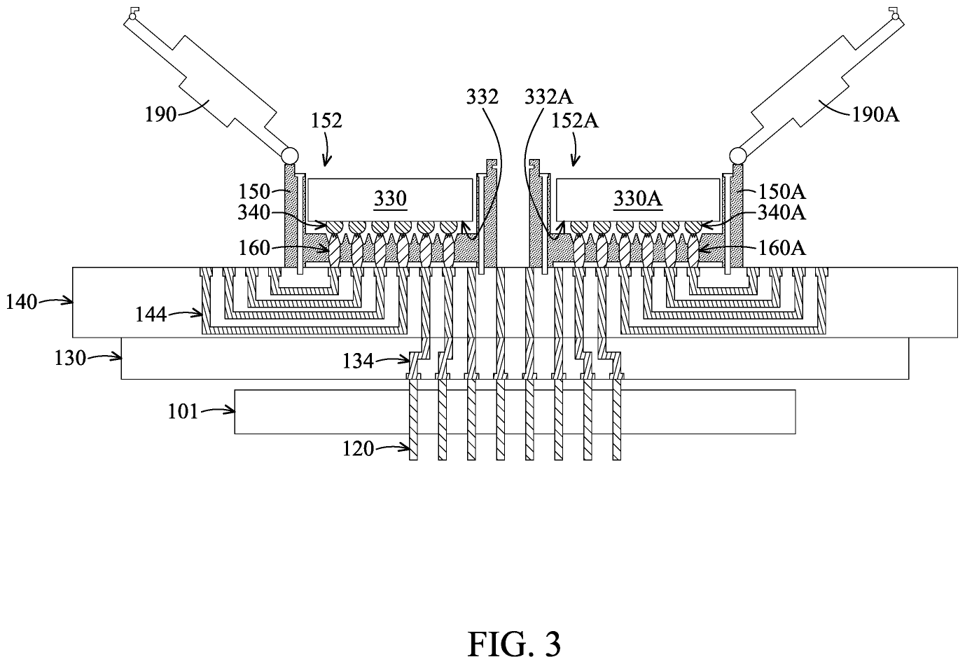

FIG. 3 is a cross-sectional view of a chip testing structure, in accordance with some embodiments. After the step of the FIG. 2, as shown in FIG. 3, the chip-containing structures 330 and 330A are provided, in accordance with some embodiments.

The chip-containing structures 330 include a chip or a package having one or more chips, in accordance with some embodiments. The chip-containing structures 170 and 330 have the same function, in accordance with some embodiments.

The chip-containing structure 330A includes a chip or a package having one or more chips, in accordance with some embodiments. The chip-containing structures 170A and 330A have the same function, in accordance with some embodiments.

The chip-containing structures 330 and 330A have different functions, in accordance with some embodiments. For example, the chip-containing structures 330 and 330A are respectively one and another of a central processing unit chip, a graphic processing unit chip, a high bandwidth memory package, a memory chip, or the like, in accordance with some embodiments.

In some embodiments, the chip-containing structure 330 is a chip. In some embodiments, the chip includes a substrate, devices, and an interconnect structure over the substrate, in accordance with some embodiments. The substrate, the devices, and the interconnect layers are not shown in figures for the purpose of simplicity and clarity.

The substrate is made of an elementary semiconductor material including silicon or germanium in a single crystal structure, a polycrystal structure, or an amorphous structure. In some other embodiments, the substrate is made of a compound semiconductor, such as silicon carbide, gallium arsenide, gallium phosphide, indium phosphide, indium arsenide, an alloy semiconductor, such as SiGe, or GaAsP, or a combination thereof. The substrate may also include multi-layer semiconductors, semiconductor on insulator (SOI) (such as silicon on insulator or germanium on insulator), or a combination thereof.

In some embodiments, the devices of the chip 330 are formed in and/or over the substrate. Examples of the various devices include active devices, passive devices, other suitable elements, or a combination thereof. The active devices may include transistors or diodes formed at a surface of the substrate. The passive devices include resistors, capacitors, or other suitable passive devices.

For example, the transistors may be metal oxide semiconductor field effect transistors (MOSFET), complementary metal oxide semiconductor (CMOS) transistors, bipolar junction transistors (BJT), high-voltage transistors, high-frequency transistors, p-channel and/or n-channel field effect transistors (PFETs/NFETs), etc. Various processes, such as front-end-of-line (FEOL) semiconductor fabrication processes, are performed to form the various device elements. The FEOL semiconductor fabrication processes may include deposition, etching, implantation, photolithography, annealing, planarization, one or more other applicable processes, or a combination thereof.

In some embodiments, isolation features (not shown) are formed in the substrate. The isolation features are used to define active regions and electrically isolate various devices formed in and/or over the substrate in the active regions. In some embodiments, the isolation features include shallow trench isolation (STI) features, local oxidation of silicon (LOCOS) features, other suitable isolation features, or a combination thereof.

The interconnect structure is formed over the devices and the substrate, in accordance with some embodiments. The interconnect structure includes a dielectric layer, wiring layers, and conductive vias, in accordance with some embodiments. The wiring layers and the conductive vias are in the dielectric layer, in accordance with some embodiments. The conductive vias are electrically connected between the wiring layers and the devices, in accordance with some embodiments.

The dielectric layer is made of an oxide-containing material (e.g., silicon oxide or tetraethyl orthosilicate (TEOS) oxide), an oxynitride-containing material (e.g., silicon oxynitride), a glass material (e.g., borosilicate glass (BSG), phosphoric silicate glass (PSG), borophosphosilicate glass (BPSG), or fluorinated silicate glass (FSG)), or a combination thereof, in accordance with some embodiments.

Alternatively, the dielectric layer includes a low-k material or a porous dielectric material having a k-value which is lower than that of silicon oxide, or lower than about 3.0 or about 2.5, in accordance with some embodiments. The wiring layers and the conductive vias are made of a conductive material, such as metal (e.g., copper, aluminum, gold, silver, or tungsten) or alloys thereof, in accordance with some embodiments.

In some embodiments, the chip-containing structure 330A is a chip. In some embodiments, the chip includes a substrate, devices, and an interconnect structure over the substrate, in accordance with some embodiments. The substrate, the devices, and the interconnect layers are not shown in figures for the purpose of simplicity and clarity.

The substrate is made of an elementary semiconductor material including silicon or germanium in a single crystal structure, a polycrystal structure, or an amorphous structure. In some other embodiments, the substrate is made of a compound semiconductor, such as silicon carbide, gallium arsenide, gallium phosphide, indium phosphide, indium arsenide, an alloy semiconductor, such as SiGe, or GaAsP, or a combination thereof. The substrate may also include multi-layer semiconductors, semiconductor on insulator (SOI) (such as silicon on insulator or germanium on insulator), or a combination thereof.

In some embodiments, the devices of the chip 330A are formed in and/or over the substrate. Examples of the various devices include active devices, passive devices, other suitable elements, or a combination thereof. The active devices may include transistors or diodes formed at a surface of the substrate. The passive devices include resistors, capacitors, or other suitable passive devices.

For example, the transistors may be metal oxide semiconductor field effect transistors (MOSFET), complementary metal oxide semiconductor (CMOS) transistors, bipolar junction transistors (BJT), high-voltage transistors, high-frequency transistors, p-channel and/or n-channel field effect transistors (PFETs/NFETs), etc. Various processes, such as front-end-of-line (FEOL) semiconductor fabrication processes, are performed to form the various device elements. The FEOL semiconductor fabrication processes may include deposition, etching, implantation, photolithography, annealing, planarization, one or more other applicable processes, or a combination thereof.

In some embodiments, isolation features (not shown) are formed in the substrate. The isolation features are used to define active regions and electrically isolate various devices formed in and/or over the substrate in the active regions. In some embodiments, the isolation features include shallow trench isolation (STI) features, local oxidation of silicon (LOCOS) features, other suitable isolation features, or a combination thereof.

The interconnect structure is formed over the devices and the substrate, in accordance with some embodiments. The interconnect structure includes a dielectric layer, wiring layers, and conductive vias, in accordance with some embodiments. The wiring layers and the conductive vias are in the dielectric layer, in accordance with some embodiments. The conductive vias are electrically connected between the wiring layers and the devices, in accordance with some embodiments.

The dielectric layer is made of an oxide-containing material (e.g., silicon oxide or tetraethyl orthosilicate (TEOS) oxide), an oxynitride-containing material (e.g., silicon oxynitride), a glass material (e.g., borosilicate glass (BSG), phosphoric silicate glass (PSG), borophosphosilicate glass (BPSG), or fluorinated silicate glass (FSG)), or a combination thereof, in accordance with some embodiments.

Alternatively, the dielectric layer includes a low-k material or a porous dielectric material having a k-value which is lower than that of silicon oxide, or lower than about 3.0 or about 2.5, in accordance with some embodiments. The wiring layers and the conductive vias are made of a conductive material, such as metal (e.g., copper, aluminum, gold, silver, or tungsten) or alloys thereof, in accordance with some embodiments.

As show in FIG. 3, the conductive bumps 340 are formed over a bottom surface 332 of the chip-containing structure 330, in accordance with some embodiments. The conductive bumps 340 are made of a conductive material, such as tin, or alloys thereof, in accordance with some embodiments.

As show in FIG. 3, conductive bumps 340A are formed over a bottom surface 332A of the chip-containing structure 330A, in accordance with some embodiments. The conductive bumps 340A are made of a conductive material, such as tin, or alloys thereof, in accordance with some embodiments.

As show in FIG. 3, the chip-containing structure 330 and the conductive bumps 340 are disposed in the chamber 152 of the housing structure 150, in accordance with some embodiments. The conductive bumps 340 are between the chip-containing structure 330 and the needles 160, in accordance with some embodiments. The conductive bumps 340 are in direct contact with the needles 160, in accordance with some embodiments.

The chip-containing structure 330 is electrically connected to the needles 120 through the conductive bumps 340, the needles 160, the conductive structure 144 of the wiring substrate 140, and the conductive structure 134 of the transformer substrate 130, in accordance with some embodiments.

As show in FIG. 3, the chip-containing structure 330A and the conductive bumps 340A are disposed in the chamber 152A of the housing structure 150A, in accordance with some embodiments. The conductive bumps 340A are between the chip-containing structure 330A and the needles 160A, in accordance with some embodiments. The conductive bumps 340A are in direct contact with the needles 160A, in accordance with some embodiments.

The chip-containing structure 330A is electrically connected to the needles 120 through the conductive bumps 340A, the needles 160A, the conductive structure 144 of the wiring substrate 140, and the conductive structure 134 of the transformer substrate 130, in accordance with some embodiments.

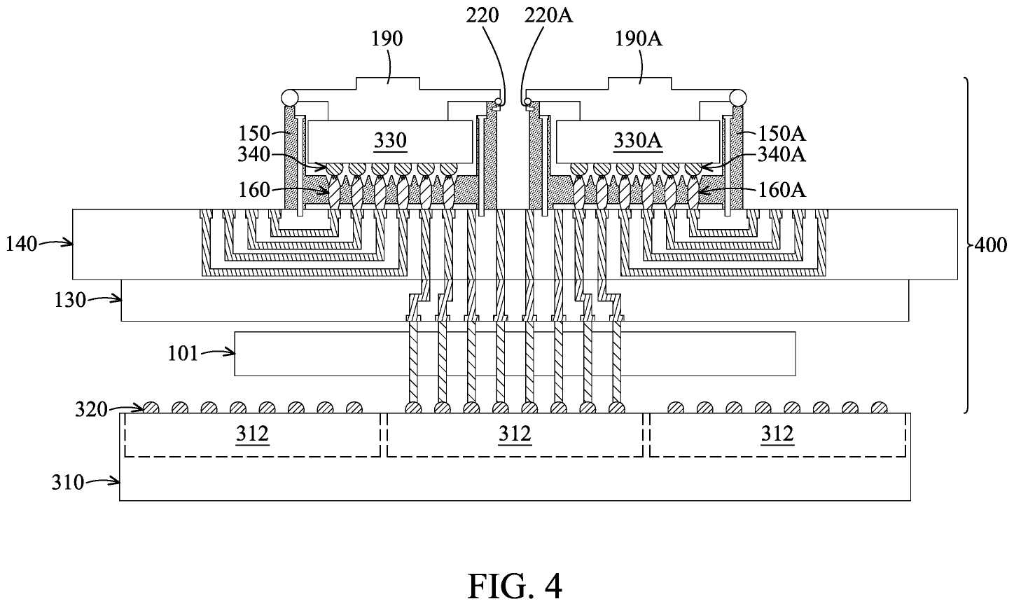

FIG. 4 is a cross-sectional view of a chip testing structure and a wafer, in accordance with some embodiments. After the step of FIG. 3, as shown in FIG. 4, the cover plates 190 and 190A are pivotally closed, in accordance with some embodiments. In this step, a chip testing structure 400 is substantially formed, in accordance with some embodiments. The chip testing structure 400 can be used to detect the chip regions 312 of the wafer 310, in accordance with some embodiments.

Processes and materials for forming the chip testing structure 400 may be similar to, or the same as, those for forming the chip testing structure 100 described above. Elements designated by the same or similar reference numbers as those in FIGS. 1 to 4 have the same or similar structures and the materials. Therefore, the detailed descriptions thereof will not be repeated herein.

In accordance with some embodiments, chip testing structures are provided. The chip testing structure has at least one chip-containing structure. The chip testing structure can not only detect the electrical quality of chip regions of a wafer, but also detect the electrical quality of the electrical connection between the chip-containing structure and each chip region. Therefore, the chip testing structure can help screen out the chip regions with poor electrical connection quality before the packaging process. As a result, the chip testing structure can prevent the chips with poor electrical connection quality from being packaged, which reduces the cost of packages and improves the yield and the performance of packages.

In accordance with some embodiments, a chip testing structure is provided. The chip testing structure includes a probe head including a substrate and a first needle passing through the substrate. The chip testing structure includes a wiring substrate over the probe head. The wiring substrate includes an insulating layer and a conductive structure in the insulating layer. The chip testing structure includes a housing structure over the wiring substrate. The housing structure has a chamber. The chip testing structure includes a second needle passing through the housing structure and connected to the conductive structure of the wiring substrate. The chip testing structure includes a chip-containing structure in the chamber and electrically connected to the first needle through the second needle and the conductive structure of the wiring substrate.

In accordance with some embodiments, a chip testing structure is provided. The chip testing structure includes a probe head including a substrate and a first needle passing through the substrate. The chip testing structure includes a wiring substrate over the probe head. The wiring substrate includes an insulating layer and a conductive structure in the insulating layer. The chip testing structure includes a housing structure over the wiring substrate. The housing structure has a chamber. The chip testing structure includes a second needle passing through the housing structure and connected to the conductive structure of the wiring substrate. The chip testing structure includes a cover plate covering the chamber of the housing structure.

In accordance with some embodiments, a chip testing structure is provided. The chip testing structure includes a probe head including a substrate and a first needle passing through the substrate. The chip testing structure includes a transformer substrate over the probe head. The transformer substrate includes a first insulating layer and a first conductive structure in the first insulating layer. The chip testing structure includes a wiring substrate over the transformer substrate. The wiring substrate includes a second insulating layer and a second conductive structure in the second insulating layer, and the first conductive structure is connected between the second conductive structure and the first needle. The chip testing structure includes a first chip-containing structure over the wiring substrate and electrically connected to the first needle through the first conductive structure and the second conductive structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A chip testing structure, comprising:
a probe head comprising a substrate and a first needle passing through the substrate;
a wiring substrate over the probe head, wherein the wiring substrate comprises an insulating layer and a conductive structure in the insulating layer;
a housing structure over the wiring substrate, wherein the housing structure has a chamber;
a second needle passing through the housing structure and connected to the conductive structure of the wiring substrate; and
a chip-containing structure in the chamber and electrically connected to the first needle through the second needle and the conductive structure of the wiring substrate.

2. The chip testing structure as claimed in claim 1, further comprising:
a cover plate over the housing structure and the chip-containing structure.

3. The chip testing structure as claimed in claim 2, wherein the cover plate is connected to the housing structure by a first pivot.

4. The chip testing structure as claimed in claim 3, further comprising:
a hook-like structure connected to an edge portion of the cover plate, wherein the cover plate is between the hook-like structure and the first pivot.

5. The chip testing structure as claimed in claim 4, wherein the hook-like structure is connected to the edge portion of the cover plate by a second pivot.

6. The chip testing structure as claimed in claim 2, wherein the cover plate has a lower surface and a protruding portion protruding from the lower surface.

7. The chip testing structure as claimed in claim 6, wherein the protruding portion of the cover plate is in direct contact with the chip-containing structure.

8. The chip testing structure as claimed in claim 1, further comprising:
a screw structure passing through the housing structure and extending into the wiring substrate.

9. The chip testing structure as claimed in claim 1, wherein the second needle is in direct contact with the conductive structure of the wiring substrate.

10. The chip testing structure as claimed in claim 1, further comprising:
a conductive bump between the chip-containing structure and the second needle.

11. A chip testing structure, comprising:
a probe head comprising a substrate and a first needle passing through the substrate;
a wiring substrate over the probe head, wherein the wiring substrate comprises an insulating layer and a conductive structure in the insulating layer;
a housing structure over the wiring substrate, wherein the housing structure has a chamber;
a second needle passing through the housing structure and connected to the conductive structure of the wiring substrate; and
a cover plate covering the chamber of the housing structure.

12. The chip testing structure as claimed in claim 11, wherein the cover plate is pivotally connected to the housing structure.

13. The chip testing structure as claimed in claim 11, further comprising:
a hook-like structure pivotally connected to an edge portion of the cover plate.

14. The chip testing structure as claimed in claim 11, further comprising:
a pillar structure passing through the housing structure and extending into the wiring substrate.

15. The chip testing structure as claimed in claim 14, wherein the housing structure is in direct contact with the wiring substrate.

16. A chip testing structure, comprising:
a probe head comprising a substrate and a first needle passing through the substrate;
a transformer substrate over the probe head, wherein the transformer substrate comprises a first insulating layer and a first conductive structure in the first insulating layer;
a wiring substrate over the transformer substrate, wherein the wiring substrate comprises a second insulating layer and a second conductive structure in the second insulating layer, and the first conductive structure is connected between the second conductive structure and the first needle; and
a first chip-containing structure over the wiring substrate and electrically connected to the first needle through the first conductive structure and the second conductive structure.

17. The chip testing structure as claimed in claim 16, further comprising:
a second chip-containing structure over the wiring substrate and electrically connected to the first needle through the first conductive structure and the second conductive structure.

18. The chip testing structure as claimed in claim 17, further comprising:
a first housing structure over the wiring substrate, wherein the first housing structure has a first chamber, and the first chip-containing structure is in the first chamber; and
a second needle passing through the first housing structure and connected to the second conductive structure of the wiring substrate.

19. The chip testing structure as claimed in claim 18, further comprising:
a second housing structure over the wiring substrate, wherein the second housing structure has a second chamber, and the second chip-containing structure is in the second chamber; and
a third needle passing through the second housing structure and connected to the second conductive structure of the wiring substrate.

20. The chip testing structure as claimed in claim 16, wherein the first conductive structure of the transformer substrate is in direct contact with the second conductive structure of the wiring substrate and the first needle.
